(19) United States
(12) Patent Application Publication
(10) Pub. No.: US 2025/0337380 A1
(43) Pub. Date: Oct. 30, 2025

(54) EQUALIZER FILTERS WITH ACTIVE INDUCTORS FOR CONTINUOUS-TIME LINEAR EQUALIZERS

(71) Applicant: Cypress Semiconductor Corporation, San Jose, CA (US)

(72) Inventors: Sai Goutham SUNKARA, San Jose, CA (US); Gary MILLER, Corbett, OR (US); Nicholas BODNARUK, Sunnyvale, CA (US); Soon-Gil JUNG, Santa Clara, CA (US)

(73) Assignee: Cypress Semiconductor Corporation, San Jose, CA (US)

(21) Appl. No.: 18/647,862

(22) Filed: Apr. 26, 2024

(51) Int. Cl. H03G 3/30; H03F 3/45; H03H 11/04; H04L 25/03

(52) U.S. Cl. CPC H03G 3/30; H03F 3/45179; H03H 11/04; H04L 25/03057; H03G 2201/103

(57) ABSTRACT

A two-stage continuous-time linear equalizer (CTLE) to increase a peaking gain includes a first stage and a second stage. The first stage comprises a first equalizer core cell and the second stage comprises a second equalizer core cell. The first equalizer core cell and the second equalizer core cell each comprise a differential amplifier comprising a first n-type metal-oxide-semiconductor (NMOS) transistor. The first equalizer core cell and the second equalizer core cell each further comprise an active inductor coupled to the differential amplifier, the active inductor comprising a second NMOS transistor and a load resistor.

### TECHNICAL FIELD

Aspects and embodiments of the present disclosure relate to serialization/deserialization systems, and in particular to equalizer filters with active inductors for continuous-time linear equalizers.

### BACKGROUND

Serialization/deserialization (SERDES) techniques enable devices to exchange data over serial data links. An example SERDES system may include a transmitter to convert parallel data into a serial data signal, a transmission channel to carry the serial data signal, and a receiver to convert the serial data signal back into parallel data. Examples of communications protocols that may use SERDES techniques include Universal Serial Bus (USB), Ethernet, Peripheral Component Interconnect Express (PCIe), and others.

### BRIEF DESCRIPTION OF DRAWINGS

Various embodiments in accordance with the present disclosure will be described with reference to the drawings, in which:

FIG. 1 is a block diagram of an example SERDES receiver for deserializing serial input data to obtain parallel output data, in accordance with an embodiment;

FIG. 2A is a block diagram of an example continuous time linear equalizer (CTLE) for equalizing and/or amplifying input signal having frequency-dependent attenuation, in accordance with an embodiment;

FIG. 2B is a plot illustrating an example equalizer core cell frequency response, in accordance with an embodiment;

FIG. 3A is a block diagram of an example equalizer filter with an active inductor, in accordance with an embodiment;

FIG. 3B is a plot illustrating an example equalizer filter frequency response, in accordance with an embodiment;

FIG. 4A is a circuit diagram of an example equalizer filter with an active inductor in accordance with an embodiment;

FIG. 4B is a circuit diagram of an example equalizer filter with an active inductor in accordance with an embodiment; and

FIG. 5 illustrates an embodiment of a Universal Serial Bus (USB) integrated circuit (IC) controller such as a USB 3.1/3.2 high-speed data controller, in accordance with an embodiment.

### DETAILED DESCRIPTION

Aspects of the present disclosure relate to equalizer filters with active inductors for continuous-time linear equalizers (CTLEs). SERDES receivers may include a variety of subsystems for processing serial data streams. For example, a SERDES receiver may include a CTLE to compensate for transmission channel attenuation that varies with frequency. A CTLE may include one or more equalizing stages, which may each further include equalizing core cells to provide signal gain and equalization to account for frequency-independent and frequency-dependent transmission channel attenuation.

SERDES receivers may face challenges related to compensating for transmission channel attenuation in a power- and area-efficient manner. In some systems, such as high-frequency serial links operating at 5-10 gigabits per second (e.g., USB), CTLEs may have three, four, or more stages of equalizer core cells to provide adequate compensation at the Nyquist frequency (e.g., at 5 GHz). As a result, these systems may experience increased power consumption and silicon area consumption due to large CTLEs. Furthermore, some equalizer core cell designs may have a non-fixed common-mode output voltage, which can lead to complications in the design of input circuitry for following stages.

Aspects of the present disclosure address the above challenges and other challenges by using equalizer filters with active inductors for continuous-time linear equalizers. An example system may include one or more of the following aspects: (i) an equalizer filter with an NMOS differential amplifier and an NMOS active inductor, (ii) a two-stage CTLE with equalizer core cells having active inductors, or (iii) a Universal Serial Bus (USB) Physical Layer (PHY) receiver with a CTLE having active inductors. These aspects are further described below.

In an embodiment, a system includes an equalizer filter with an NMOS differential amplifier and an NMOS active inductor. The NMOS differential amplifier includes load resistors, a gain control resistor network, and a boost control capacitor network. The frequency response of the differential amplifier is set by the gain control network and the boost control network. The gain control network sets the gain of the differential amplifier for the operating bandwidth, while the boost control network sets the peaking gain of a high-frequency bandwidth associated with attenuation of a transmission channel.

The NMOS active inductor is coupled to the load resistors and may be enabled or disabled. When enabled, the frequency response of the differential amplifier is increased by a second peaking gain of the high-frequency bandwidth contributed by the active inductor. This increased peaking gain may be advantageous for achieving a desired high-frequency boost with fewer equalizing filters, less silicon area, and less power. The active inductor provides additional area savings over filters with passive inductors and can be programmatically enabled or disabled, in contrast to passive inductors. Furthermore, the differential amplifier and active inductor may also be biased to have a fixed common-mode output voltage, which may simplify input circuitry of following stages.

In an embodiment, a system includes a two-stage CTLE with equalizer core cells having active inductors. The equalizer core cells may have increased peaking gains associated with the active inductors as described above, which enables the two-stage CTLE to have fewer stages than may otherwise be needed to achieve a desired gain and/or equalization. Thus, a two-stage CTLE may use less silicon are and less power than, e.g., a 3- or 4-stage CTLE.

In an embodiment, a system includes a USB PHY receiver with a CTLE having active inductors. The CTLE may have increased peaking gains associated with the active inductors as described above, which enables the USB PHY to have a smaller CTLE than may otherwise be needed to achieve a desired gain and/or equalization. Thus, the USB PHY may use less silicon and less power than other designs.

### Serdes Receivers

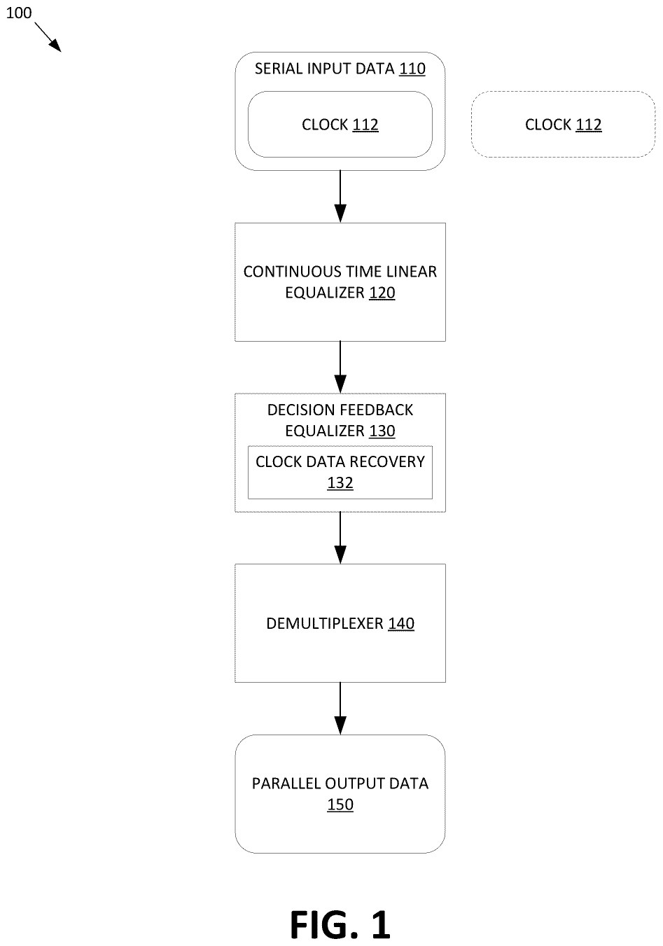

FIG. 1 is a block diagram of an example SERDES receiver 100 for deserializing serial input data 110 to obtain parallel output data 150, in accordance with an embodiment. SERDES receiver 100 includes continuous-time linear equalizer (CTLE) 120, decision feedback equalizer (DFE) 130, and demultiplexer 140. In various embodiments, SERDES receiver 100 may include more, fewer, or different components than those depicted in FIG. 1, and the components may process input data 110 in a different order than depicted in FIG. 1.

SERDES receiver 100 may be associated with a corresponding SERDES transmitter (not depicted). The transmitter may perform various functions, such as converting data into a serial data stream, adding parity bits or other types of channel coding to the stream, generating a clock signal, and embedding the clock signal in the stream, generating low-voltage differential signaling (LVDS) signals, amplifying the signals, transmitting the signals, or similar.

SERDES receiver 100 may further be associated with a transmission channel (not depicted), such as a copper cable, optical fiber, wireless link, or other medium. Data signals and clock signals may be separate or combined in the transmission channel. The transmission channel may induce attenuation on carried signals that varies with frequency. For example, the transmission channel may cause increased attenuation at high frequencies (e.g., near the Nyquist frequency) relative to low frequencies (e.g., near direct current (DC)).

SERDES receiver 100 may receive the serial data stream from the channel and convert it to another data format (e.g., parallel data) for processing or storage. Receiver functions may include amplifying the received signals, consuming LVDS signals, extracting a clock signal from the stream, performing parity checking or other types of stream decoding, or similar.

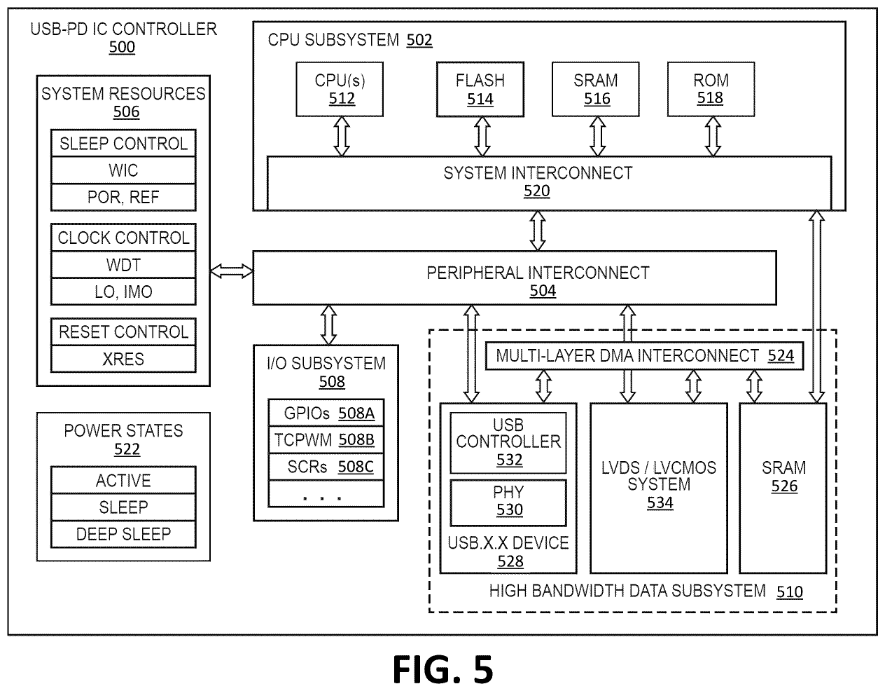

In an example of the above-mentioned SERDES components, a Universal Serial Bus (USB) system may include a USB transmitter, a USB receiver, and a USB cable (transmission channel). USB systems are further described with reference to FIG. 5.

Serial input data 110 may correspond to a voltage signal, current signal, optical signal, wireless signal, or other type of signal. The signal may be singled-ended or differential in various embodiments. For example, serial input data 110 may be an LVDS signal. Serial input data 110 may be associated with clock signal 112 having a fixed frequency value (e.g., measured in kilohertz, megahertz, gigahertz, etc.). In some embodiments, clock signal 112 may be embedded in serial input data 110 (indicated by solid outline), while in other embodiments, clock signal 112 may be a separate signal (indicated by dashed outline). Serial input data 110 may further be associated with channel attenuation due to characteristics of the transmission channel described above.

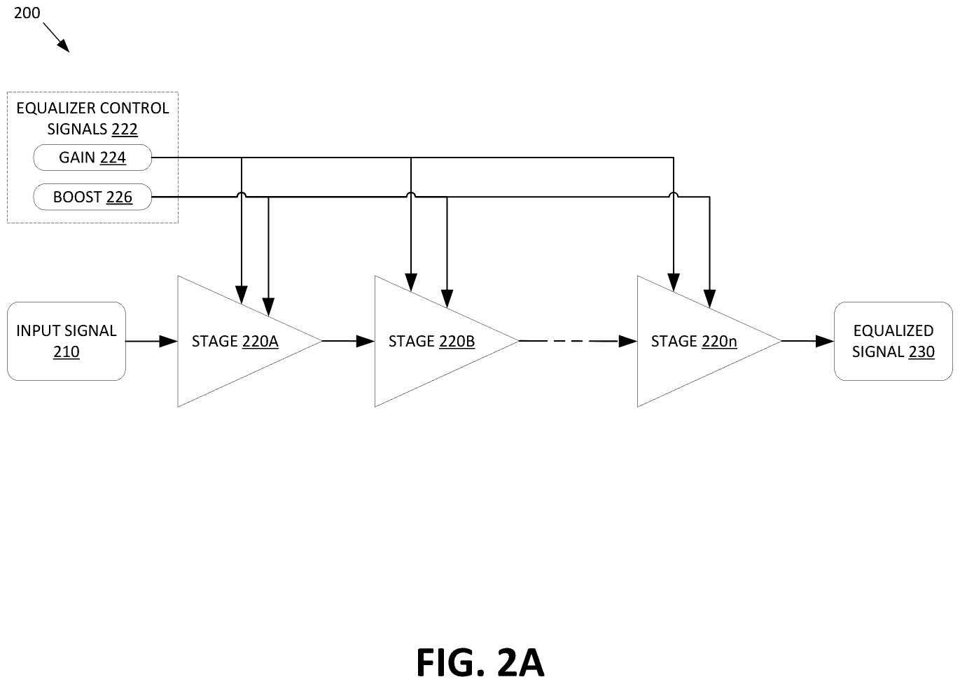

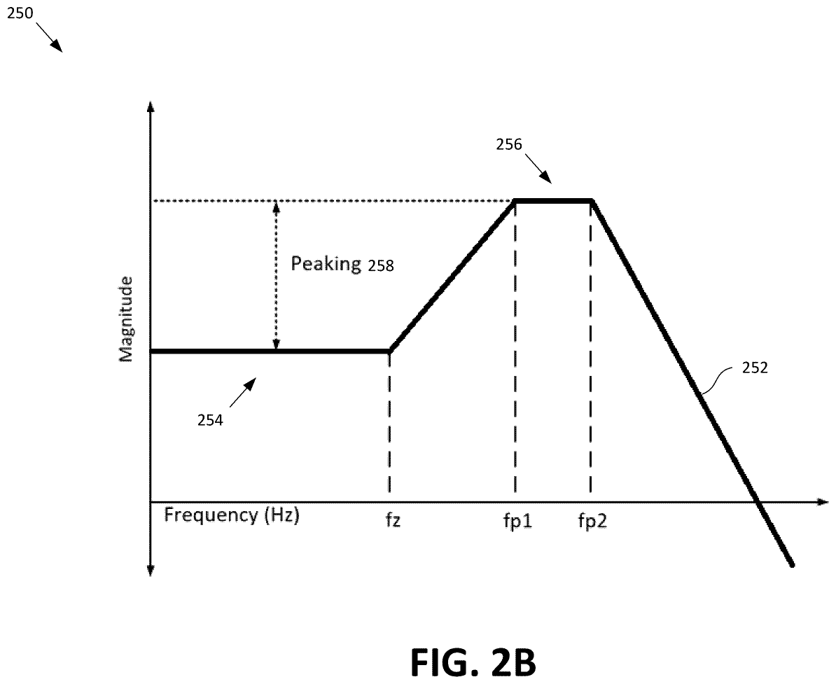

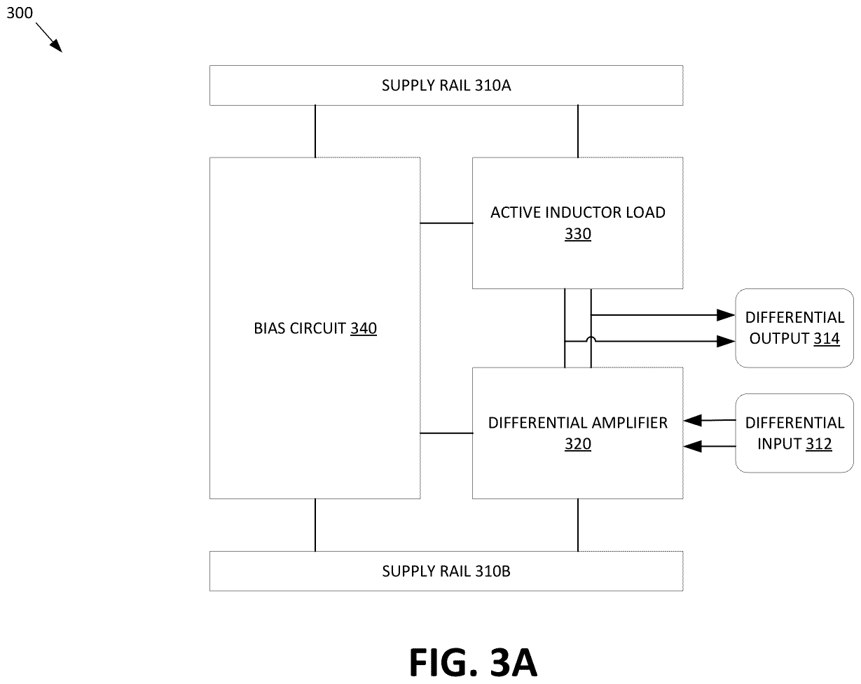

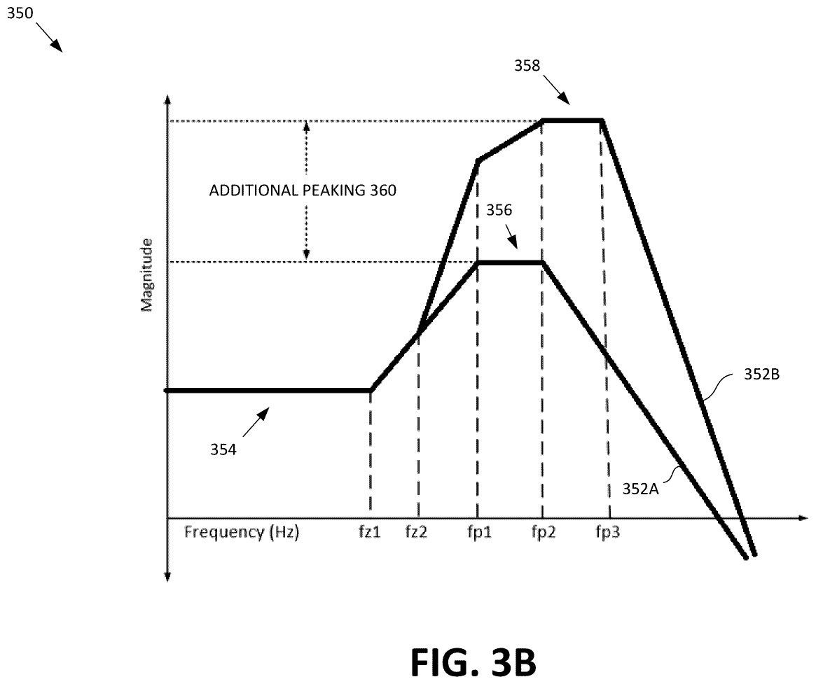

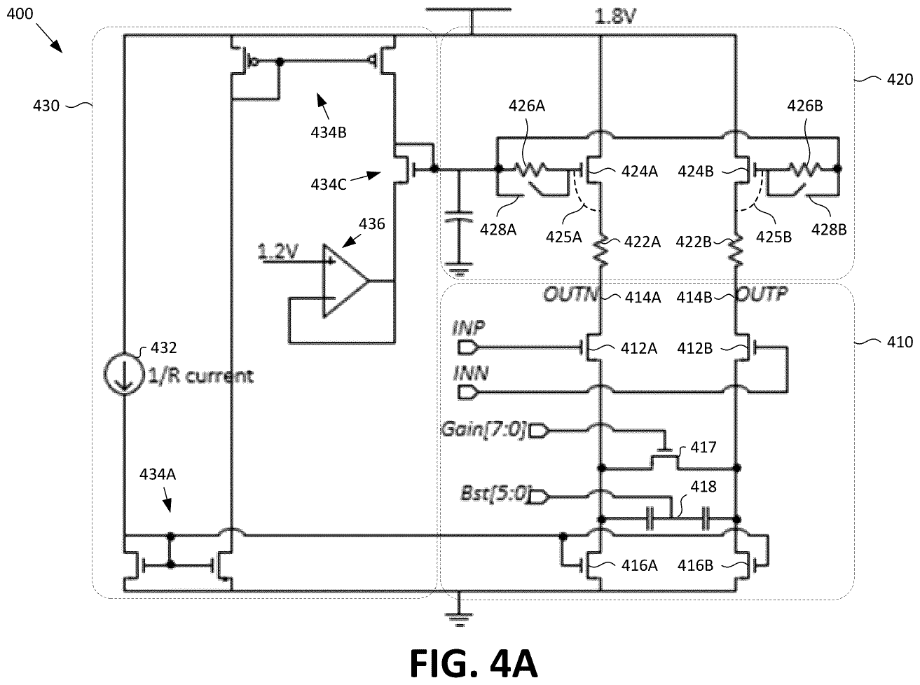

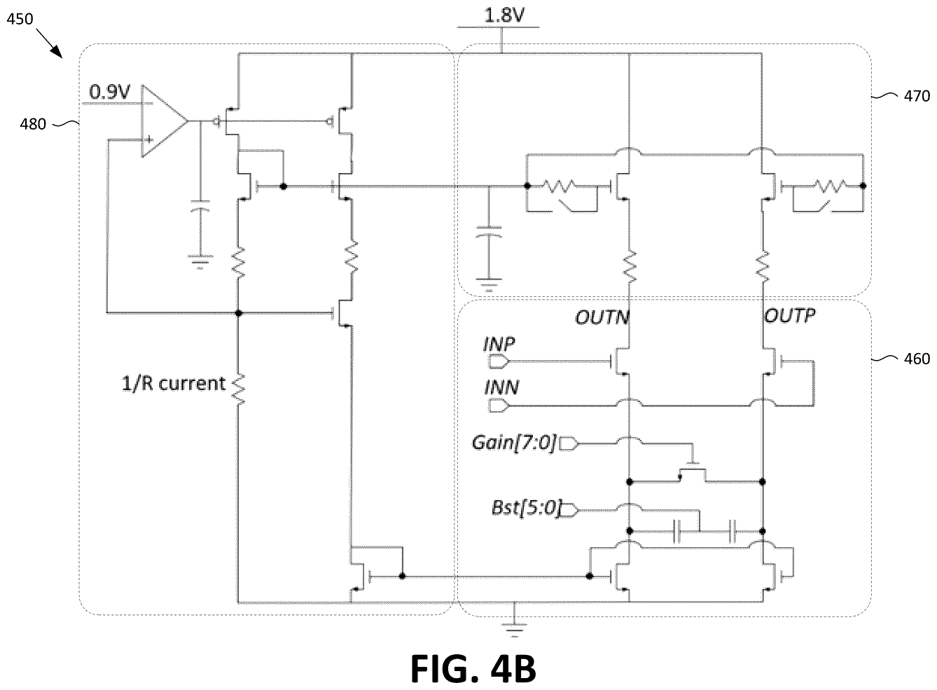

CTLE 120 modifies serial input data 110 to provide an equalizing gain that amplifies the incoming signal and/or offsets frequency-dependent attenuation of the transmission channel. For example, CTLE 120 may provide frequency-independent gain to the whole signal and/or frequency-dependent boost to higher-frequency components associated with increased attenuation in the transmission channel. Thus, CTLE 120 may approximate an inverse of the transmission channel attenuation. CTLE 120 may include one or more stages of equalizer core cells to affect the overall desired gain characteristics of CTLE 120. CTLEs are further described with reference to FIG. 2A-B. Equalizer core cells in the form of equalizer filters are further described with reference to FIGS. 3A-4B.

DFE 130 quantizes the output of CTLE 120 into symbols and further equalizes the output of CTLE 120 by canceling inter-symbol interference (ISI). DFE 130 may use clock signal 112 to sample the output of CTLE 120. In various embodiments, clock signal 112 may be used directly if separate from serial input data 110, or clock signal 112 may be recovered using clock data recovery component 132. DFE 130 may include one or more slicers for making symbol decisions, and one or more summers for adding slicer output to the incoming signal as feedback to cancel ISI.

Demultiplexer 140 converts a serial stream of symbols output by DFE 130 into separate data lines each corresponding to a symbol's relative position in the stream. Demultiplexer 140 may be associated with a width value (e.g., 8, 16, 32) corresponding to the number of data lines and the number of symbols processed at a time. Demultiplexer 140 may be associated with a clock input (e.g., clock signal 112) and may provide a fractional clock output related to the width. Demultiplexer 140 may include a shift register with the number of flip-flops equal to the width value.

Parallel output data 150 may correspond to a plurality of symbols (e.g., bits) represented in serial input data 110. The symbols may be stored in a register, buffer, memory, or other type of storage, or may be retransmitted on a parallel channel. The symbols may be associated with a width, such as a byte, half-word, word, or similar. The width may correspond to a width of demultiplexer 140. Parallel data 510 may further be associated with clock value (not depicted), which may be a fraction of clock signal 112 determined by the width.

### Continuous-Time Linear Equalizers

FIG. 2A is a block diagram of an example continuous time linear equalizer (CTLE) 200 for equalizing and/or amplifying input signal 210 having frequency-dependent attenuation, in accordance with an embodiment. CTLE 200 includes stages 220A-n and equalizer control signals 222. In various embodiments, CTLE 200 may include more, fewer, or different components than those depicted in FIG. 2A, and the components may process input signal 210 in a different order than depicted in FIG. 2A. In an embodiment, CTLE 200 is CTLE 120 of SERDES receiver 100 of FIG. 1.

Input signal 210 may correspond to serial input data 110 of FIG. 1. As described with reference to serial input data 110, input signal 210 may be a voltage signal or other type of signal and may be single-ended or differential (e.g., an LVDS signal). Input signal 210 may be associated with a separate clock signal or may embed a clock signal.

Stages 220A-n each provide gain and/or equalization to their respective input signals (input signal 210 for stage 220A, and the outputs of respective previous stages for stages 220B-n) and generate respective output signals (inputs of respective following stages for stages 220A-(n−1) and equalized signal 230 for stage 220n). Each of stages 220A-n may be or may include an equalizer core cell providing a portion of CTLE 200's overall gain and equalization. Stages 200A-n may include the same or different equalizer core cells in various embodiments. An example equalizer core cell frequency response plot is depicted in FIG. 2B and described below.

In an embodiment, CTLE 200 includes two stages 220A-B to generate equalized signal 230. Each of stages 220A-B includes an equalizer core cell with an active inductor. In contrast, equalizer core cells without active inductors may be included in a CTLE having three, four, or more stages 220A-n.

Equalizer control signals 222 control variable characteristics of stages 220A-n, such as magnitudes of gain and equalization, bandwidths of gain and equalization, or similar. Equalizer control signals 222 may correspond to analog control signals such as a digital-to-analog converter (DAC) output, or digital signals such as a binary code or a Gray code. In various embodiments, a shared control signal may be routed to each of stages 224A-n, or each of stages 224A-n may alternatively be associated with respective independent control signals. Equalizer control signals 222 may be generated by a processor associated with CTLE 200, such as one of the various components described with reference to USB IC controller 500 described with reference to FIG. 5.

In an embodiment, equalizer control signals 222 include gain control signal 224 and boost control signal 226. Gain control signal 224 may correspond to a first gain in a first bandwidth, and boost control signal 226 may correspond to a second gain in a second bandwidth. For example, the first gain may be a uniform gain across the operating bandwidth of CTLE 200 (which may correspond to a transmission channel bandwidth), and the second gain may be an equalizing gain across a narrower boost bandwidth (which may correspond to a high-frequency attenuation bandwidth of a transmission channel). The first bandwidth may include the second bandwidth in full or in part. Example gain and boost bandwidths are further described below with reference to FIG. 2B.

FIG. 2B is a plot 250 illustrating an example equalizer core cell frequency response 252, in accordance with an embodiment. The x-axis indicates response frequency (e.g., Hertz, radians per second, etc.), and the y-axis indicates response magnitude (e.g., volts, decibels, etc.). The x-axis and y-axis may indicate linear or logarithmic scales in various embodiments. Frequency response 252 as depicted in plot 250 may be an approximation of a frequency response, and various equalizer core cells may have different frequency responses in various embodiments.

Frequency response 252 includes gain bandwidth 254, which may be a uniform or frequency-independent gain region across a full or partial bandwidth of frequency response 252. Frequency response 252 further includes boost bandwidth 256, which may be a frequency-dependent gain region across a high-frequency partial bandwidth of frequency response 252 (e.g., a bandwidth at or near the Nyquist frequency, or a bandwidth higher than DC). As previously mentioned, boost bandwidth 256 may be fully or partially included in gain bandwidth 254. Thus, boost bandwidth 256 may provide additional peaking 258 over the flat gain of gain bandwidth 254, which may offset high-frequency attenuation of an input signal.

Equalizer Filters with Active Inductors

FIG. 3A is a block diagram of an example equalizer filter 300 with an active inductor, in accordance with an embodiment. Equalizer filter 300 includes supply rails 310A-B, differential amplifier 320, active inductor load 330, and bias circuit 340. In various embodiments, equalizer filter 300 may include more, fewer, or different components than those depicted in FIG. 3A. In an embodiment, equalizer filter 300 is an equalizer core cell included in one or more of stages 220A-n of CTLE 200 of FIG. 2A. Equalizer filter 300 may be used for purposes other than equalizer core cells of CTLEs in various embodiments.

Supply rails 310A-B may provide fixed voltage references and sufficient current for equalizer filter 300. Supply rail 310A may provide a standard or nonstandard voltage, such as 0.6V, 1.2V, 1.8V, 3.3V, 5V, etc. Supply rail 310A may provide a ground reference (e.g., 0V) or a negative voltage rail such as −0.6V, −1.2V, −1.8V, −3.3V, −5V, etc. In some embodiments, additional supply rails (not depicted) may provide additional voltages. For example, a 1.2V rail may be provided in addition to a 1.8V rail (e.g., supply rail 310A) and ground (e.g., supply rail 310B), as depicted in FIG. 4A.

Differential input 312 may correspond to input signal 210 or respective outputs of stages 220A-n of FIG. 2A. Differential output 314 may correspond to equalized signal or respective inputs of stages 220A-n of FIG. 2A. For example, differential input 312 and differential output 314 may be LVDS signals.

Differential amplifier 320 may include an NMOS transistor to amplify differential input 312 and generate differential output 314. Differential amplifier 320 may further include a gain control network and a boost control network, which may correspond to gain control signal 224 and boost control signal 226 of FIG. 2A. The gain control and boost control networks may be used to set gain and boost bandwidths and/or magnitudes for differential amplifier 320. Example differential amplifier circuits are further described with reference to FIGS. 4A-B.

Active inductor load 330 may include an NMOS transistor to imitate an inductor and a load resistor to provide additional peaking to the boost bandwidth of differential amplifier 320. Active inductor load 330 may include switches to enable or disable active inductor load 330. Example active inductor circuits are further described with reference to FIGS. 4A-B.

Bias circuit 340 may be a shared biasing circuit for differential amplifier 320 and active inductor load 330, and may include current sources, voltage sources, current mirrors, and other circuitry to provide bias currents and voltages to differential amplifier 320 and active inductor load 330. Bias circuit 340 may set a fixed common-mode voltage for differential output 314 by appropriately biasing differential amplifier 320 and/or active inductor load 330. Various characteristics of bias circuit 340, such as transistor width-to-length ratios, may be determined using analysis, simulation, experimentation, or other techniques to achieve desired characteristics for equalizer filter 300. Example bias circuits are further described with reference to FIGS. 4A-B.

FIG. 3B is a plot 350 illustrating example equalizer filter frequency responses 352A-B, in accordance with an embodiment. The x-axis indicates response frequency (e.g., Hertz, radians per second, etc.), and the y-axis indicates response magnitude (e.g., volts, decibels, etc.). The x-axis and y-axis may indicate linear or logarithmic scales in various embodiments. Frequency responses 352A-B as depicted in plot 350 may be approximations of a frequency response, and various equalizer filters may have different frequency responses in various embodiments.

Frequency response 352A may be a frequency response of equalizer filter 300 when active inductor load 330 is disabled, and may correspond to frequency response 252 of an equalizer core cell. Frequency response 352A includes gain bandwidth 354, which may be a uniform or frequency-independent gain region across a full or partial bandwidth of frequency response 352A. Frequency response 352A further includes boost bandwidth 356, which may be a frequency-dependent gain region across a high-frequency partial bandwidth of frequency response 352A. As previously mentioned, boost bandwidth 356 may be fully or partially included in gain bandwidth 354. In an embodiment, frequency response 352A may be associated with differential amplifier 320, which may provide a zero and two poles (e.g., fz1, fp1, fp2) to frequency response 352A.

Frequency response 352B may be a frequency response of equalizer filter 300 when active inductor load 330 is enabled. Frequency response 352B includes gain bandwidth 354 as described above. Frequency response 352B further includes increased boost bandwidth 358, which may correspond to boost bandwidth 356 with additional peaking 360 provided by active inductor load 330. The peaking provided by differential amplifier 320 and active inductor load 330 may combine to provide increased boost bandwidth 358, and the resulting gain may be greater than in boost bandwidth 356. As with boost bandwidth 356, increased boost bandwidth 358 may be fully or partially included in gain bandwidth 354. In an embodiment, active inductor load 330 may provide a zero and a pole (e.g., fz2, fp3) to frequency response 352B.

FIG. 4A is a circuit diagram of an example equalizer filter 400 with an active inductor in accordance with an embodiment. Equalizer filter 400 includes differential amplifier 410, active inductor load 420, and bias circuit 430. In various embodiments, equalizer filter 400 may include more, fewer, or different components than those depicted in FIG. 4A. In an embodiment, differential amplifier 410, active inductor load 420, and bias circuit 430 correspond to differential amplifier 320, active inductor load 330, and bias circuit 440 of FIG. 3, respectively.

Differential amplifier 410 includes differential input NMOS transistors 412A-B, differential output voltage reference nodes 414A-B, current biasing NMOS transistors 416A-B, gain network 417, and boost network 418. Differential input NMOS transistors 412A-B are coupled to input voltage nodes, differential output voltage reference nodes 414A-B (which are further coupled to load resistors 422A-B), current biasing NMOS transistors 416A-B, gain network 417, and boost network 418, which each perform various functions detailed below. Differential amplifier 410 is arranged in two symmetrical paths, with the left path including elements 412A-416A and the right path including elements 412B-416B. This arrangement may be referred to as a “long-tailed pair” in an embodiment. In operation, differential amplifier 410 receives a differential input signal (e.g., differential input 312) at a pair of differential input voltage reference nodes coupled to the gate terminals of NMOS transistors 412A-B (e.g., “INP” and “INN”) and provides an amplified differential output signal (e.g., differential output 314) at differential output voltage reference nodes 414A-B (e.g., “OUTP” and “OUTN”).

Gain network 417 tunes the gain of differential amplifier 410 and may provide frequency-independent amplification across the operating bandwidth of differential amplifier 410. For example, gain network 417 may set gain levels for bandwidths 254 and 354 depicted in FIGS. 2B and 3B, respectively. In operation, gain network 417 may be configured by an external control signal (e.g., “Gain [7:0]”). For example, gain network 417 may be configured by an analog signal of a digital-to-analog converter (DAC), a binary code, a Gray code, or similar. The external control signal may correspond to one or more of equalizer control signals 222 of FIG. 2. In an embodiment, gain network 417 includes a gain control NMOS transistor operating in linear mode (e.g., having variable resistance). In an embodiment, gain network 417 includes a gain control resistor network.

Boost network 418 tunes the high-frequency boost of differential amplifier 410 and may provide additional gain in a narrow bandwidth corresponding to increased attenuation in a transmission channel. For example, boost network 418 may set boost levels for bandwidths 256 and 356 depicted in FIGS. 2B and 3B, respectively. In operation, boost network 418 may be configured by an external control signal (e.g., “Bst[5:0]”). For example, boost network 418 may be configured by a DAC, a binary code, a Gray code, or similar. The external control signal may correspond to one or more of equalizer control signals 222 of FIG. 2. In an embodiment, boost network 418 includes a boost control capacitor network.

Active inductor load 420 includes load resistors 422A-B, active inductor NMOS transistors 424A-B, active inductor resistors 426A-B, and active inductor switches 428A-B. Active inductor NMOS transistors 424A-B are coupled to load resistors 422A-B (via the source terminals), a positive voltage rail (via the drain terminals), and active inductor resistors and switches 426A-B and 428A-B (via the gate terminals). Active inductor resistors and switches 426A-B and 428A-B are further coupled to bias circuit 430. Active inductor load 420 is arranged in two symmetrical paths corresponding to the two paths of differential amplifier 410, with the left path including elements 422A-428A and the right path including elements 422B-428B. Switches 428A-B may be used to enable or disable the active inductors in the left and right paths, respectively.

In operation, active inductor NMOS transistors 424A-B may imitate the impedance of passive inductors using resistors 426A-B and intrinsic gate-source capacitances 425A-B to create a shunt peaking effect, when appropriately biased as described below. Active inductor NMOS transistors 424A-B in combination with load resistors 422A-B, may provide addition gain in a narrow bandwidth corresponding to increased attenuation in a transmission channel. For example, active inductor load 420 may set additional boost levels for bandwidth 358 of FIG. 3B. Active inductor NMOS transistors 424A-B in combination with load resistors 422A-B may further provide a stable common mode voltage for differential output voltage reference nodes 414A-B.

Bias circuit 430 includes current source 432, current mirrors 434A-C, and voltage source 436. In operation, bias circuit 430 may provide appropriate bias voltages and currents to differential amplifier 410 and active inductor load 420 to enable various characteristics described herein.

Current mirror 434A is an NMOS current mirror and provides currents for current mirror 434B and current biasing NMOS transistors 416A-B of differential amplifier 410. The two NMOS transistors of current mirror 434A may have the same or different width-to-length (W/L) ratios in various embodiments, which may be determined by analysis, simulation, experimentation, etc. to achieve various characteristics described herein. Current mirror 434B is a PMOS current mirror and provides current for current mirror 434C. Similarly, the two PMOS transistors of current mirror 434B may have the same or different W/L ratios in various embodiments. Current mirror 434C and voltage source 436 bias the active inductors of active inductor load 420 and provide a fixed common-mode voltage at differential voltage output reference nodes 414A-B.

FIG. 4B is a circuit diagram of an example equalizer filter 450 with an active inductor in accordance with an embodiment. Equalizer filter 450 includes differential amplifier 460, active inductor load 470, and bias circuit 480. In various embodiments, equalizer filter 450 may include more, fewer, or different components than those depicted in FIG. 4B. In an embodiment, differential amplifier 460, active inductor load 470, and bias circuit 480 correspond to differential amplifier 320, active inductor load 330, and bias circuit 440 of FIG. 3A, respectively.

Aspects described with reference to differential amplifier 410 and active inductor load 420 of FIG. 4A may apply to differential amplifier 460 and active inductor load 470, respectively, in various embodiments. Bias circuit 480, while different than bias circuit 430 of FIG. 4A, may similarly bias differential amplifier 460 and active inductor load 470 to enable various characteristics described herein. As with bias circuit 430, various parameters such as fixed currents, fixed voltages, and transistor W/L ratios may be determined using analysis, simulation, experimentation, etc. Other types of bias circuits not depicted in FIGS. 4A-B may be used in various embodiments.

### Universal Serial Bus Systems

FIG. 5 illustrates an embodiment of a Universal Serial Bus (USB) integrated circuit (IC) controller 500 such as a USB 3.1/3.2 high-speed data controller, in accordance with an embodiment. USB IC controller 500 may be implemented as a single-chip IC controller manufactured on a semiconductor die. In another example, USB IC controller 500 may be a single-chip IC that is manufactured as a System-on-Chip (SoC). In other embodiments, USB IC controller 500 may be a multi-chip module encapsulated in a single semiconductor package.

USB IC controller 500 includes CPU (Central Processing Unit) subsystem 502, peripheral interconnect 504, system resources 506, input/output (I/O) subsystem 508, high bandwidth data subsystem 510, and various terminals (e.g., pins) that are configured for receiving and sending signals.

CPU subsystem 502 may include one or more CPUs 512, flash memory 514, SRAM (Static Random Access Memory) 516, ROM (Read Only Memory) 518, etc. that are coupled to system interconnect 520. Each CPU 512 is a suitable processor that can operate in an IC or a SoC device. Flash memory 514 is non-volatile memory (e.g., NAND flash, NOR flash, etc.) that is configured for storing data, programs, and/or other firmware instructions. Flash memory 514 is tightly coupled within CPU subsystem 502 for improved access times. SRAM 516 is volatile memory that is configured for storing data and firmware instructions accessed by each CPU 512. ROM 518 is read-only memory (or other suitable storage medium) that is configured for storing boot-up routines, configuration parameters, and other firmware parameters and settings. System interconnect 520 is a system bus (e.g., a single-level or multi-level Advanced High-Performance Bus, or AHB) that is configured as an interface that couples the various components of CPU subsystem 502 to each other, as well as a data and control interface between the various components of CPU subsystem 502 and peripheral interconnect 504.

Peripheral interconnect 504 is a peripheral bus (e.g., a single-level or multi-level AHB) that provides the primary data and control interface between CPU subsystem 502 and its peripherals and other resources, such as system resources 506, I/O subsystem 508, and high bandwidth data subsystem 510. Peripheral interconnect 504 may include various controller circuits (e.g., direct memory access (DMA) controllers), which may be programmed to transfer data between peripheral blocks without burdening CPU subsystem 502. In various embodiments, each of the components of CPU subsystem 502 and peripheral interconnect 504 may be different with each choice or type of CPU, system bus, and/or peripheral bus.

System resources 506 include various electronic circuits that support the operation of USB IC controller 500 in its various states and modes. For example, system resources 506 may include a power subsystem having analog and/or digital circuits required for each controller state/mode such as, for example, sleep control circuits, wake-up interrupt controller (WIC), power-on-reset (POR), voltage and/or current reference (REF) circuits, etc. In some embodiments, the power subsystem may also include circuits that allow USB IC controller 500 to draw and/or provide power from/to external sources with several different voltage and/or current levels and to support controller operation in several power states 522 (e.g., such as active state, sleep state, and a deep sleep state with clocks turned off). Further, in some embodiments CPU subsystem 502 may be optimized for low-power operation with extensive clock gating and may include various internal controller circuits that allow CPU subsystem 502 to operate in the various power states 522. For example, CPU subsystem 502 may include a wake-up interrupt controller that is configured to wake CPU subsystem 502 from a sleep state, thereby allowing power to be switched off when the IC chip is in the sleep state. System resources 506 may also include a clock subsystem having analog and/or digital circuits for clock generation and clock management such as, for example, clock control circuits, watchdog timer (WDT) circuit(s), internal low-speed oscillator (ILO) circuit(s), and internal main oscillator (IMO) circuit(s), etc. System resources 506 may also include analog and/or digital circuit blocks that provide reset control and support external reset (XRES).

I/O subsystem 508 includes several different types of I/O blocks and subsystems. For example, I/O subsystem 508 includes GPIO (general purpose input output) blocks 508A, TCPWM (timer/counter/pulse-width-modulation) blocks 508B, and SCBs (serial communication blocks) 508C. GPIOs 508A include analog and/or digital circuits configured to implement various functions such as, for example, pull-ups, pull-downs, input threshold select, input and output buffer enabling/disabling, multiplex signals connected to various I/O pins, etc. TCPWM blocks 508B include analog and/or digital circuits configured to implement timers, counters, pulse-width modulators, decoders, and various other analog/mixed signal elements that are configured to operate on input/output signals. SCBs 508C include analog and/or digital circuits configured to implement various serial communication interfaces such as, for example, I2C (inter-integrated circuit), SPI (serial peripheral interface), UART (universal asynchronous receiver/transmitter), CAN (Controller Area Network) interface, CXPI (Clock extension Peripheral Interface), etc.

High bandwidth data subsystem 510 provides DMA (direct memory access) data transfers from LVDS (low-voltage differential signaling)/LVCMOS (low-voltage CMOS) input to USB output at speeds up to 10 Gbps for USB 3.2 Gen 2, 20 Gbps for USB 3.2 Gen 2×2 transfer rates, 40 Gbps for USB 4, etc. High bandwidth data subsystem 510 includes multi-layer DMA interconnect 524, SRAM 526 for buffering USB data, USB device 528 that includes one or more USB PHY (physical interface) 530 for implementing USB 2.X, 3.X, 4.X, etc. endpoints with transmission speeds of 480 Mbps, 5 Gbps, 10 Gbps, 20 Gbps, 40 Gbps, etc., one or more USB controllers 532 and related circuitry, and LVDS/LVCMOS subsystem 534 for providing an LVDS/LVCMOS interface.

In accordance with the SERDES techniques and equalizer filters described herein, USB PHY 530 included in high bandwidth data subsystem 510 may include SERDES receiver 100 described with reference to FIG. 1, which may further include CTLE 200 of FIG. 2A (e.g., a two-stage CTLE). Each stage of CTLE 200 may correspond to equalizer filter 300 of FIG. 3A and may include an active inductor load. In an embodiment, USB PHY 530 may include more than one SERDES receiver 100. For example, USB PHY 530 may include two SERDES receives 100 to support two RX signals in USB 3.2 Gen 2×2. In various embodiments, aspects described herein with reference to FIGS. 1-4B may similarly or alternatively be included in LVDS/LVCMOS subsystem 534 or other subsystems of USB IC controller 500.

In the above description, numerous details are set forth. It will be apparent, however, to one of ordinary skill in the art having the benefit of this disclosure, that embodiments of the present disclosure may be practiced without these specific details. In some instances, well-known structures and devices are shown in block diagram form, rather than in detail, in order to avoid obscuring the description.

Some portions of the detailed description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “receiving,” “adjusting,” or the like, refer to the actions and processes of a computing system, or similar electronic computing device, that manipulates and transforms data represented as physical (e.g., electronic) quantities within the computing system's registers and memories into other data similarly represented as physical quantities within the computing system memories or registers or other such information storage, transmission or display devices.

The words “example” or “exemplary” are used herein to mean serving as an example, instance or illustration. Any aspect or design described herein as “example’ or “exemplary” is not necessarily to be construed as preferred or advantageous over other aspects or designs. Rather, the use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “some embodiments” throughout is not intended to mean the same embodiment or embodiments unless described as such.

Embodiments described herein may also relate to an apparatus for performing the operations herein. This apparatus may be specially constructed for the required purposes, or it may comprise a general-purpose computer selectively activated or reconfigured by firmware. Such firmware may be stored in a non-transitory computer-readable storage medium, such as, but not limited to, device registers, read-only memories (ROMs), random access memories (RAMs), EPROMS, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium capable of storing, encoding, or carrying a set of instructions for execution by the machine or device and that causes the machine/device to perform any one or more of the methodologies of the present embodiments. The term “computer-readable storage medium” shall accordingly be taken to include, but not be limited to, solid-state memories, optical media, magnetic media, and any medium that is capable of storing a set of instructions for execution by the machine/device and that causes the machine/device to perform any one or more of the methodologies of the present embodiments.

The algorithms and displays presented herein are not inherently related to any particular device or other apparatus. Various systems (e.g., system-on-chip (SoC)) may be used with firmware in accordance with the teachings herein, or it may prove convenient to construct a more specialized device or apparatus to perform the required method steps. The required structure for a variety of these systems will appear from the description herein. In addition, the present embodiments are not described with reference to any particular programming language. It will be appreciated that a variety of programming languages may be used to implement firmware consistent the teachings of the embodiments as described herein.

The above description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid unnecessarily obscuring the present disclosure. Thus, the specific details set forth above are merely exemplary. Particular embodiments may vary from these exemplary details and still be contemplated to be within the scope of the present disclosure.

It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

In the above description, for purposes of explanation, numerous specific details are set forth in order to provide a thorough understanding of the present disclosure. It will be evident, however, to one skilled in the art that the present disclosure may be practiced without these specific details. In other instances, well-known circuits, structures, and techniques are not shown in detail, but rather in a block diagram in order to avoid unnecessarily obscuring an understanding of this description.

Reference in the description to “one embodiment,” “an embodiment,” or “some embodiments” means that a particular feature, structure, or characteristic described in connection with the embodiment(s) is included in at least one embodiment of the disclosure. The phrase “in one embodiment” or “in some embodiments” located in various places in this description does not necessarily refer to the same embodiment(s).

What is claimed is:

1. A two-stage continuous-time linear equalizer (CTLE) to increase a peaking gain, the two-stage CTLE comprising:
a first stage comprising a first equalizer core cell; and
a second stage comprising a second equalizer core cell, wherein the first equalizer core cell and the second equalizer core cell each comprise:
a differential amplifier comprising a first n-type metal-oxide-semiconductor (NMOS) transistor; and
an active inductor load coupled to the differential amplifier, the active inductor load comprising a second NMOS transistor and a load resistor.

2. The two-stage CTLE of claim 1, wherein:
the differential amplifier is to provide a frequency response having a first gain in a first bandwidth and a first peaking gain in a second bandwidth;
the active inductor load is to provide a second peaking gain in the second bandwidth, the first peaking gain and the second peaking gain combining to obtain an increased peaking gain in the second bandwidth; and
the increased peaking gain is greater than the first peaking gain.

3. The two-stage CTLE of claim 2, wherein:
the first bandwidth corresponds to a transmission channel bandwidth of a transmission channel associated with the two-stage CTLE;
the second bandwidth corresponds to a high-frequency attenuation bandwidth of the transmission channel; and
the first bandwidth comprises the second bandwidth.

4. The two-stage CTLE of claim 1, wherein the first NMOS transistor of the differential amplifier is coupled to:
an input voltage reference node of a pair of differential input voltage reference nodes;
an output voltage reference node of a pair of differential output voltage reference nodes, wherein the output voltage reference node is further coupled to the load resistor;
a boost-control capacitor network; and
one of: a gain control NMOS transistor operating in linear mode, or a gain-control resistor network.

5. The two-stage CTLE of claim 4, wherein the pair of differential output voltage reference nodes corresponds to a fixed common-mode output voltage associated with a shared biasing circuit coupled to each of the differential amplifier and the active inductor load.

6. The two-stage CTLE of claim 1, wherein:
a source terminal of the second NMOS transistor is coupled to the load resistor;
a drain terminal of the second NMOS transistor is coupled to a positive voltage rail;
a gate terminal of the second NMOS transistor is coupled to a second resistor and a switch;
the second resistor and the switch are each coupled to a biasing circuit; and
a gate-source capacitance of the second NMOS transistor is associated with a shunt peaking effect of the active inductor load.

7. The two-stage CTLE of claim 1, wherein:
the differential amplifier corresponds to a first zero, a first pole, and a second pole;
the active inductor load corresponds to a second zero and a second pole; and
the second zero and second pole correspond to a high-frequency attenuation bandwidth of a transmission channel associated with the two-stage CTLE.

8. An equalizer filter comprising:
a differential amplifier comprising a first n-type metal-oxide-semiconductor (NMOS) transistor, the differential amplifier to provide a frequency response having a first gain in a first bandwidth and a first peaking gain in a second bandwidth; and
an active inductor load coupled to the differential amplifier, the active inductor load comprising a second NMOS transistor and a load resistor, the active inductor load to provide a second peaking gain in the second bandwidth, the first peaking gain and the second peaking gain combining to obtain an increased peaking gain in the second bandwidth.

9. The equalizer filter of claim 8, wherein:
the first bandwidth corresponds to a transmission channel bandwidth of a transmission channel associated with the equalizer filter;
the second bandwidth corresponds to a high-frequency attenuation bandwidth of the transmission channel; and
the first bandwidth comprises the second bandwidth.

10. The equalizer filter of claim 8, wherein the first NMOS transistor of the differential amplifier is coupled to:
an input voltage reference node of a pair of differential input voltage reference nodes;
an output voltage reference node of a pair of differential output voltage reference nodes, wherein the output voltage reference node is further coupled to the load resistor;
a boost control capacitor network; and
one of: a gain control NMOS transistor operating in linear mode, or a gain control resistor network.

11. The equalizer filter of claim 10, wherein the pair of differential output voltage reference nodes corresponds to a fixed common-mode output voltage associated with a shared biasing circuit coupled to each of the differential amplifier and the active inductor load.

12. The equalizer filter of claim 8, wherein:
a source terminal of the second NMOS transistor is coupled to the load resistor;
a drain terminal of the second NMOS transistor is coupled to a positive voltage rail;
a gate terminal of the second NMOS transistor is coupled to a second resistor and a switch;
the second resistor and the switch are each coupled to a biasing circuit; and
a gate-source capacitance of the second NMOS transistor is associated with a shunt peaking effect of the active inductor load.

13. The equalizer filter of claim 8, wherein:
the differential amplifier corresponds to a first zero, a first pole, and a second pole;
the active inductor load corresponds to a second zero and a second pole; and
the second zero and second pole correspond to a high-frequency attenuation bandwidth of a transmission channel associated with the equalizer filter.

14. A Universal Serial Bus (USB) Physical Layer (PHY) of a USB system, the USB PHY comprising:
a continuous-time linear equalizer (CTLE) equalizer core cell comprising:
a differential amplifier comprising a first n-type metal-oxide-semiconductor (NMOS) transistor; and
an active inductor load coupled to the differential amplifier, the active inductor load comprising a second NMOS transistor and a load resistor.

15. The USB PHY of claim 14, wherein:
the differential amplifier is to provide a frequency response having a first gain in a first bandwidth and a first peaking gain in a second bandwidth;
the active inductor load is to provide a second peaking gain in the second bandwidth, the first peaking gain and the second peaking gain combining to obtain an increased peaking gain in the second bandwidth; and
the increased peaking gain is greater than the first peaking gain.

16. The USB PHY of claim 15, wherein:
the first bandwidth corresponds to a transmission channel bandwidth of a transmission channel associated with the USB PHY;
the second bandwidth corresponds to a high-frequency attenuation bandwidth of the transmission channel; and
the first bandwidth comprises the second bandwidth.

17. The USB PHY of claim 14, wherein the first NMOS transistor of the differential amplifier is coupled to:
an input voltage reference node of a pair of differential input voltage reference nodes;
an output voltage reference node of a pair of differential output voltage reference nodes, wherein the output voltage reference node is further coupled to the load resistor;
a boost control capacitor network; and
one of: a gain control NMOS transistor operating in linear mode, or a gain control resistor network.

18. The USB PHY of claim 17, wherein the pair of differential output voltage reference nodes corresponds to a fixed common-mode output voltage associated with a shared biasing circuit coupled to each of the differential amplifier and the active inductor load.

19. The USB PHY of claim 14, wherein:
a source terminal of the second NMOS transistor is coupled to the load resistor;
a drain terminal of the second NMOS transistor is coupled to a positive voltage rail;
a gate terminal of the second NMOS transistor is coupled to a second resistor and a switch;
the second resistor and the switch are each coupled to a biasing circuit; and
a gate-source capacitance of the second NMOS transistor is associated with a shunt peaking effect of the active inductor load.

20. The USB PHY of claim 14, wherein:
the differential amplifier corresponds to a first zero, a first pole, and a second pole;
the active inductor load corresponds to a second zero and a second pole; and
the second zero and second pole correspond to a high-frequency attenuation bandwidth of a transmission channel associated with the USB PHY.
